(19) United States
(12) Patent Application Publication
(10) Pub. No.: US 2024/0379331 A1
(43) Pub. Date: Nov. 14, 2024

(54) MICROWAVE PLASMA APPLICATOR WITH REPLACEABLE DIELECTRIC PLATE

(71) Applicant: Applied Materials, Inc., Santa Clara, CA (US)

(72) Inventors: Thai Cheng Chua, Cupertino, CA (US); Kelvin Chan, San Ramon, CA (US); Adam Fischbach, Campbell, CA (US); Farzad Houshmand, Mountain View, CA (US); Christian Valencia, Alhambra, CA (US); Philip Allan Kraus, San Jose, CA (US)

(21) Appl. No.: 18/144,745

(22) Filed: May 8, 2023

(51) Int. Cl. H01J 37/32; H05H 1/46

(52) U.S. Cl. CPC H01J 37/32495; H01J 37/32247; H01J 37/32357; H05H 1/463

(57) ABSTRACT

Embodiments disclosed herein include an applicator for microwave plasma generation. In an embodiment, the applicator comprises a resonator body with a hole into an axial center of the resonator body, where the resonator body comprises a first dielectric material. In an embodiment, the applicator further comprises a pin inserted into the hole, where the pin is an electrically conductive material. In an embodiment, the applicator further comprises a plate under the resonator body, where the plate comprises a second dielectric material that is different than the first dielectric material.

### BACKGROUND

### 1) Field

Embodiments relate to the field of semiconductor manufacturing and, in particular, to microwave plasma applicators with replaceable dielectric plates.

### 2) Description of Related Art

In semiconductor manufacturing, some processes require the use of a remote plasma source. A remote plasma source includes an antechamber that is fluidically coupled to the main processing chamber. The plasma is struck in the antechamber and excited gas molecules flow out an exhaust that couples the antechamber to the main processing chamber. In this way, the plasma is moved away from the surface of the substrate that is being processed in the main processing chamber.

In some applications, the remote plasma source comprises a resonating body, which can sometimes be referred to as a puck. A conductive pin is inserted into a hole in the axial center of the resonating body. The conductive pin is coupled to the power source. In some instances the power source may be a microwave power source. The dimensions and material composition of the resonating body may be selected in order to provide a desired resonance mode in the resonating body. For example, the resonating body may operate in a single resonance mode.

### SUMMARY

Embodiments disclosed herein include an applicator for microwave plasma generation. In an embodiment, the applicator comprises a resonator body with a hole into an axial center of the resonator body, where the resonator body comprises a first dielectric material. In an embodiment, the applicator further comprises a pin inserted into the hole, where the pin is an electrically conductive material. In an embodiment, the applicator further comprises a plate under the resonator body, where the plate comprises a second dielectric material that is different than the first dielectric material.

Embodiments disclosed herein include a remote plasma source. In an embodiment, the remote plasma source comprises a resonator body, where the resonator body comprises a first dielectric material. In an embodiment, a housing is around the resonator body, where the housing comprises a volume in which a plasma can be formed. In an embodiment, a plate is between the resonator body and the volume, where the plate comprises a second dielectric material that is different than the first dielectric material.

Embodiments disclosed herein include a semiconductor processing tool. In an embodiment, the tool comprises a chamber, and a remote plasma source coupled to the chamber. In an embodiment, the remote plasma source comprises a plate, and a resonator body on the plate. In an embodiment, the resonator body comprises a first dielectric material and an outer surface of the plate comprises a second dielectric material that is different than the first dielectric material. In an embodiment, an exhaust is coupled to the chamber.

### BRIEF DESCRIPTION OF THE DRAWINGS

FIG. 1 is a perspective view illustration of a microwave applicator with a resonator body over a plate, where the resonator body and the plate have different material compositions, in accordance with an embodiment.

FIG. 2 is a perspective view illustration of a remote plasma source that includes a microwave applicator in accordance with an embodiment.

FIG. 3A is a cross-sectional illustration of a remote plasma source with a microwave applicator that comprises a resonator body over a plate, where the resonator body and the plate comprise different material compositions, in accordance with an embodiment.

FIG. 3B is a cross-sectional illustration of a remote plasma source with a microwave applicator that comprises a resonator body over a plate, where the plate has a coating around all surfaces, in accordance with an embodiment.

FIG. 3C is a cross-sectional illustration of a remote plasma source with a microwave applicator that comprises a resonator body over a plate, where the plate has a coating over a bottom surface, in accordance with an embodiment.

FIG. 4A is a perspective view illustration of a microwave applicator with a plurality of resonator bodies over a plate, where the resonator bodies are a different material than the plate, in accordance with an embodiment.

FIG. 4B is a perspective view illustration of a microwave applicator with a plurality of resonator bodies over a plate with a coating over at least one surface, in accordance with an embodiment.

FIG. 5A is an illustration of a semiconductor processing tool with a remote plasma source that includes a microwave applicator, in accordance with an embodiment.

FIG. 5B is an illustration of a semiconductor processing tool with a first remote plasma source before the main processing chamber and a second remote plasma source in the foreline, in accordance with an embodiment.

FIG. 6 illustrates a block diagram of an exemplary computer system that may be used in conjunction with a processing tool, in accordance with an embodiment.

### DETAILED DESCRIPTION

Systems described herein include microwave plasma applicators with replaceable dielectric plates. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, remote plasma sources may be necessary for some semiconductor processes in order to protect the substrate from the plasma. In some embodiments, the remote plasma source may be a microwave plasma source. More particularly, embodiments disclosed herein include solid state microwave power sources. The use of a solid state microwave power source provides a smaller form factor than traditional microwave plasma sources. For example, embodiments disclosed herein may not use large magnetrons, waveguides, and the like in order to transfer the microwave power from the power source to the applicator. Accordingly, embodiments allow for compact remote plasma sources.

In an embodiment, the microwave plasma applicator may comprise a resonator body and a plate. The resonator body may be provided on the plate. That is, the plate may be between the generated plasma and the resonator body. Both the resonator body and the plate are a dielectric material. Typically, the resonator body and the plate are formed from the same dielectric material. In some instances, the plate and the resonator body may be formed as a single monolithic structure.

Structures such as these have competing design requirements. For example, the resonator body may require a material composition (and dimensions) that enable a desired mode of resonance. For example, a single mode resonance may be used in some instances. However, the plate also needs to have a resistance to the plasma environment. Accordingly, a balance between plasma resistance and mode of resonance must be obtained. This can lead to undesirable dimensions of the applicator (e.g., larger dimensions), as well as providing sub-optimal resistance to the plasma environment.

Therefore, embodiments disclosed herein include a microwave applicator architecture with a resonator body that comprises a first dielectric material and a plate that comprises a second dielectric material that is different than the first dielectric material. That is, the resonator body may be a discrete component that sits on (or is otherwise coupled to) the plate. This allows for the design of the resonator body to be optimized for producing the desired mode of resonance with a desired form factor, while also enabling high resistance to the plasma environment. In some instances, the modular construction of the microwave applicator allows for easy modification in order to accommodate different plasma chemistries. For example, the plate may be swapped for a different material plate when the plasma chemistry is changed. Additionally, the plate may be coated with a material that is resistant to a particular plasma chemistry.

In some embodiments, the microwave applicator may include a single plate and a single resonator body. Such embodiments may be used for compact remote plasma systems. However, embodiments are not limited to such configurations. For example, the microwave applicator may include a single plate with a plurality of resonator bodies arranged across the plate. Such embodiments may allow for additional microwave power to be coupled into the plasma, at the expense of a larger form factor.

Embodiments disclosed herein allow for the integration of remote plasma sources in various locations of the semiconductor processing tool. In one embodiment, the remote plasma source is provided upstream of the main processing chamber. For example, the remote plasma source may include an antechamber in which the plasma is generated, and excited gas flows out an exhaust of the remote plasma source into the main processing chamber. Additionally, embodiments may integrate a remote plasma source downstream of the main processing chamber. For example, a remote plasma source may be provided along the foreline. Such an embodiment may allow for improved cleaning of the foreline and exhaust system.

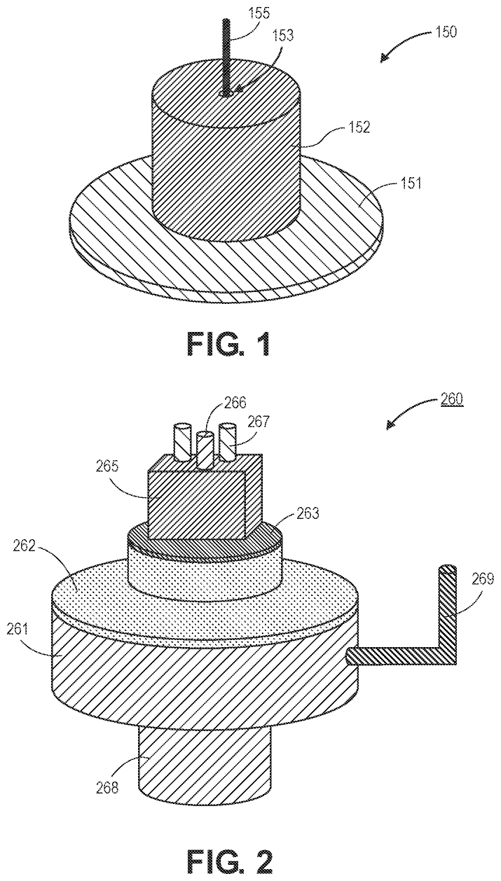

Referring now to FIG. 1, a perspective view illustration of a microwave applicator 150 is shown, in accordance with an embodiment. In an embodiment, the microwave applicator 150 comprises a plate 151 and a resonator body 152. The resonator body 152 may rest on a top surface of the plate 151. The resonator body 152 may be removably coupled to the plate 151. That is, the plate 151 may be removed from the resonator body 152. This allows for changing out the plate 151 in order to accommodate different plasma chemistries.

In an embodiment, the resonator body 152 may comprise a hole 153. The hole 153 may be at an axial center of the resonator body 152. The hole 153 is sized to receive an electrically conductive pin 155. The pin 155 may be electrically coupled to a solid state microwave power source (not shown). As such, microwave power may be delivered to the resonator body 152.

In the illustrated embodiment, the resonator body 152 is cylindrical. Though, it is to be appreciated that other shapes may be used for the resonator body 152 (e.g., prisms, elliptical shapes, etc.). Similarly, the plate 151 may be cylindrical. Other shapes may be used for the plate 151. For example, the plate may be a rectangular prism or the like. In an embodiment, a thickness of the plate 151 may be smaller than a diameter of the plate 151 (or a width or length of the plate 151). In an embodiment, a thickness of the plate 151 may be approximately 10 mm or less, or approximately 5 mm or less. As used herein, “approximately” may refer to a range of values within ten percent of the stated value. For example, approximately 10 mm may refer to a range from 9 mm to 11 mm.

In an embodiment, the resonator body 152 may be a first dielectric material and the plate 151 may be a second dielectric material that is different than the first dielectric material. In a particular embodiment, the first dielectric material may comprise alumina (e.g., aluminum oxide Al₂O₃). Though, other dielectric materials may also be used for the first dielectric material of the resonator body 152. In an embodiment, the second dielectric material may comprise quartz, alumina, sapphire, MgF₂, yttrium aluminum garnet, YF₃, Y₂O₃, Y₄Al₂O₉, Y₃Al₅O₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.

Referring now to FIG. 2, a perspective view illustration of a remote plasma source 260 is shown, in accordance with an embodiment. In an embodiment, the remote plasma source 260 may comprise a housing. The housing may include a lower portion 261 and an upper portion 262. The lower portion 261 and the upper portion 262 may enclose a microwave applicator (not visible in FIG. 2). The microwave applicator may be similar to the microwave applicator described above with respect to FIG. 1. For example, the microwave applicator may include a resonator body that is provided over a plate. The bottom of the plate may be exposed to a volume in which the remote plasma is formed. The interior construction of the remote plasma source 260 is described in greater detail below. In an embodiment, the lower portion 261 and the upper portion 262 of the housing may be an electrically conductive material. For example, the lower portion 261 and the upper portion 262 may comprise aluminum or the like. The lower portion 261 and the upper portion 262 may be electrically grounded in some embodiments.

In an embodiment, a spacer 263 may be provided over the upper portion 262 of the housing. The spacer 263 may be coupled to a matching unit 265. The matching unit 265 may enable impedance matching between the microwave power source (not shown) and the plasma load. The matching unit 265 may have any suitable configuration common to existing matching architectures. In an embodiment, the matching unit 265 may comprise a power input 266. The power input 266 may be configured to couple with a cable for transmitting the microwave power. The matching unit 265 may be actively cooled. For example, a fluid input 267 and a fluid output 267 may be provided on the matching unit 265. The input/output 267 may be fluidically coupled to a liquid cooling reservoir (not shown).

In an embodiment, a gas input 269 may be coupled into the housing. The gas input 269 may provide one or more processing gasses into the chamber within the housing. For example, processing gasses such as, but not limited to, hydrogen containing gases, fluorine containing gasses, oxygen containing gasses, chlorine containing gasses, and the like may be provided along gas input 269. Inert gasses (e.g., nitrogen, argon, etc.) may also be provided through the gas input 269.

In an embodiment, the remote plasma source 260 may also comprise an exhaust 268. The exhaust 268 may be coupled to the lower portion 261 of the housing. The exhaust 268 may be coupled to the main processing chamber (not shown). As such, excited gasses from the plasma generated in a chamber in the housing can flow into the main processing chamber.

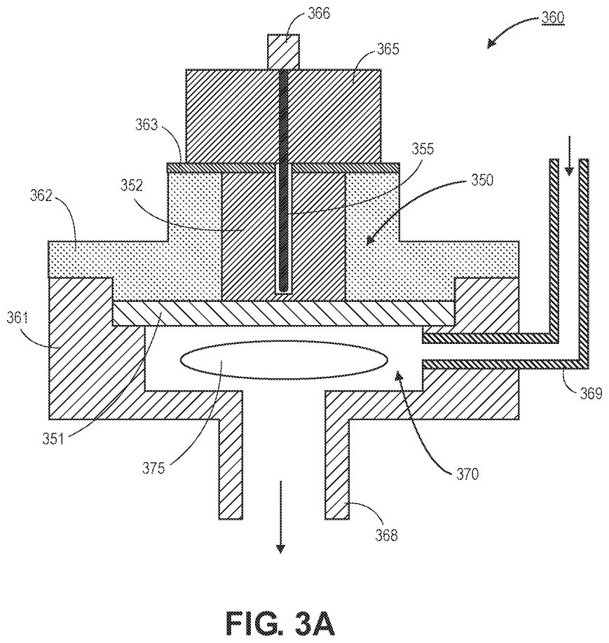

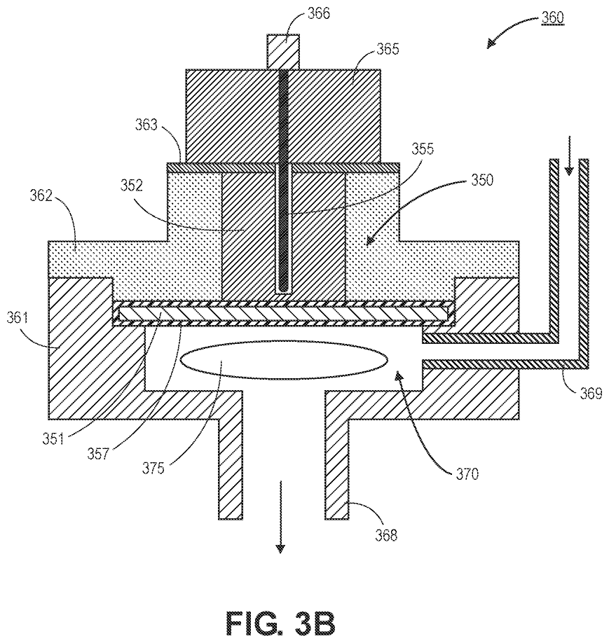

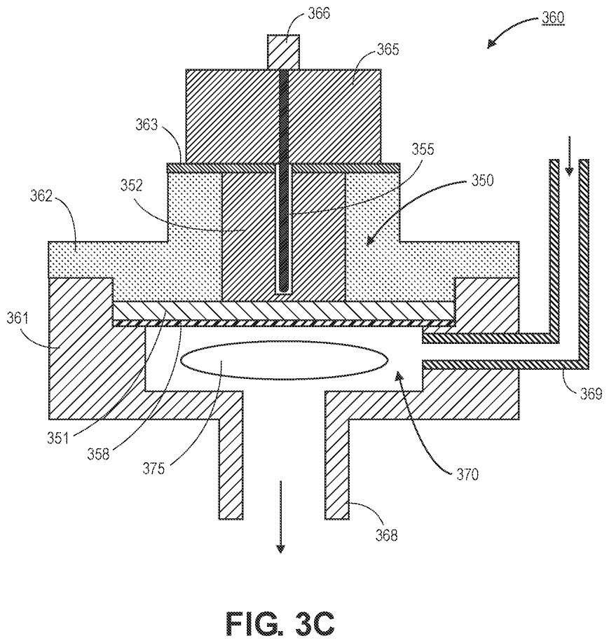

Referring now to FIGS. 3A-3C, a series of cross-sectional illustrations depicting various remote plasma sources 360 is shown. The remote plasma sources 360 in FIGS. 3A-3C may be similar to the remote plasma source 260 in FIG. 2. FIGS. 3A-3C differ from each other with respect to the structure of the microwave applicators 350.

Referring now to FIG. 3A, a cross-sectional illustration of a remote plasma source 360 is shown, in accordance with an embodiment. As shown, the remote plasma source 360 may comprise a housing with a lower portion 361 and an upper portion 362. The lower portion 361 of the housing may define at least a portion of a chamber 370. The plasma 375 may be generated in the chamber 370. In embodiments where the remote plasma source 360 is provided upstream of the main processing chamber (not shown), the chamber 370 may be referred to as an antechamber. The chamber 370 may be fluidically coupled to the main processing chamber through an exhaust 368 at the bottom of the remote plasma source 360. In an embodiment, the chamber 370 may be fed gasses from gas input 369. While a single gas input 369 is shown, it is to be appreciated that multiple gas inputs 369 may be used in some embodiments.

In an embodiment, the microwave applicator 350 may be provided within the housing. For example, sidewalls of the resonator body 352 may be surrounded by the upper portion 362 of the housing. The plate 351 under the resonator body 352 may be contacted by both the lower portion 361 and the upper portion 362 of the housing. More particularly, the lower portion 361 may comprise a ledge on which the plate 351 is supported.

In an embodiment, the plate 351 separates the resonator body 352 from the chamber 370. The plate 351 may have a thickness that is approximately 10 mm or less, or approximately 5 mm or less. In an embodiment, the plate 351 has a diameter that is wider than a diameter of the chamber 370. In a particular embodiment, a diameter of the plate 351 may be approximately 12 cm or smaller, or approximately 6 cm or smaller.

In an embodiment, the plate 351 separates the resonator body 352 from the chamber 370. In an embodiment, the resonator body 352 includes a pin 355 that extends down a hole in an axial center of the resonator body 352. In one embodiment, the axial center of the resonator body 352 is aligned with an axial center of the exhaust 368. The pin 355 may be coupled to the matching unit 365 and a connector 366. The matching unit 365 may be separated from the resonator body 352 by a spacer 363.

In an embodiment, the resonator body 352 may comprise a first dielectric material, and the plate 351 may comprise a second dielectric material. In a particular embodiment, the first dielectric material is different than the second dielectric material. That is, a material selection of the resonator body 352 is decoupled from the material selection for the plate 351. This allows for both the resonator body 352 and the plate 351 to be optimized for given processing conditions. For example, the plate 351 may be optimized to withstand a plasma environment within the chamber 370 without significant erosion or other wear. Additionally, the plate 351 may be swapped out with a plate 351 with a different material if the plasma chemistry is changed. In an embodiment, the first dielectric material and the second dielectric material may include, but are not limited to quartz, alumina, sapphire, MgF₂, yttrium aluminum garnet, YF₃, Y₂O₃, Y₄Al₂O₉, Y₃Al₅O₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.

Referring now to FIG. 3B, a cross-sectional illustration of a remote plasma source 360 is shown, in accordance with an additional embodiment. In an embodiment, the remote plasma source 360 in FIG. 3B may be substantially similar to the remote plasma source 360 in FIG. 3A, with the exception of the microwave applicator 350. Instead of having a bare plate 351, the plate 351 in FIG. 3B is coated with coating 357. In an embodiment, the coating 357 may be provided around all exterior surfaces of the plate 351. A uniform coating 357 may be provided. That is, a thickness of the coating 357 and the material composition of the coating 357 may be uniform across the plate 351.

In an embodiment, the use of a coating 357 allows for even greater flexibility in the design of the microwave applicator 350. For example, the plate 351 may be a material selected for improved mechanical properties. The coating 357 may then be used as a protective barrier for the plate 351. As such, the plate 351 is protected from the plasma environment of the chamber 370. In an embodiment, the coating 357 may have a thickness that is approximately 1,000 μm or less, or approximately 500 μm or less.

In some embodiments, the use of the coating 357 may allow for the plate 351 to be the same material as the resonator body 352. For example, the plate 351 and the resonator body 352 may both comprise alumina. In such embodiments, the coating 357 is a different material than the plate 351 and the resonator body 352. In an embodiment, the coating 357 may include, but is not limited to, MgF₂, YF₃, CaF₂, BaF₂, LiF, or NiF₂.

Referring now to FIG. 3C, a cross-sectional illustration of a remote plasma source 360 is shown, in accordance with an additional embodiment. In an embodiment, the remote plasma source 360 may be similar to the remote plasma source 360 in FIG. 3B, with the exception of the coating. Instead of having a uniform coating 357 around the entire plate 351, the embodiment shown in FIG. 3C includes a coating 358 that is provided over a single surface of the plate 351. More particularly, the coating 358 is provided on a surface of the plate 351 that is exposed to the plasma environment in the chamber 370. In an embodiment, the coating 358 may have a thickness that is approximately 1,000 μm or less, or approximately 500 μm or less. The coating 358 may span the entire bottom surface of the plate 351.

In an embodiment, the coating 358 may contact the lower portion 361 of the housing. More particularly, the coating 358 may contact a ledge of the lower portion 361 that is used to support the plate 351. In an embodiment, the top surface of the plate 351 may be in direct contact with the resonator body 352. The top surface of the plate 351 may also directly contact the upper portion 362 of the housing.

In some embodiments, the use of the coating 358 may allow for the plate 351 to be the same material as the resonator body 352. For example, the plate 351 and the resonator body 352 may both comprise alumina. In such embodiments, the coating 358 is a different material than the plate 351 and the resonator body 352. In an embodiment, the coating 358 may include, but is not limited to, MgF₂, YF₃, CaF₂, BaF₂, LiF, or NiF₂.

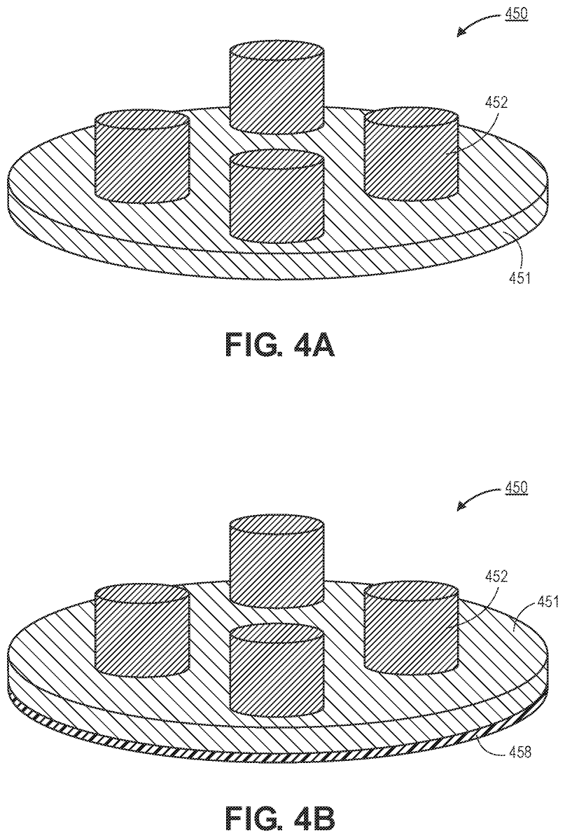

Referring now to FIG. 4A, a perspective view illustration of a microwave applicator 450 is shown, in accordance with an additional embodiment. In an embodiment, the microwave applicator 450 comprises a plate 451 and a plurality of resonator bodies 452. The resonator bodies 452 may rest on a top surface of the plate 451. The resonator bodies 452 may be removably coupled to the plate 451. That is, the plate 451 may be removed from the resonator bodies 452. This allows for changing out the plate 451 in order to accommodate different plasma chemistries.

In an embodiment, the resonator bodies 452 may be arranged over the plate 451 in any suitable configuration. While four resonator bodies 452 are shown in FIG. 4A, it is to be appreciated that any number of resonator bodies 452 may be used in accordance with embodiments disclosed herein. In an embodiment, the resonator bodies 452 may include holes (not shown) at an axial center of each resonator body 452. This allows for a conductive pin to be inserted into each of the resonator bodies 452.

In the illustrated embodiment, the resonator bodies 452 are cylindrical. Though, it is to be appreciated that other shapes may be used for the resonator bodies 452 (e.g., prisms, elliptical shapes, etc.). In some embodiments, each of the resonator bodies 452 may have substantially the same shape and dimensions. Though, in other embodiments, resonator bodies 452 may have different shapes or dimensions. In an embodiment, the plate 451 may also be cylindrical. Other shapes may be used for the plate 451 as well. For example, the plate may be a rectangular prism or the like. In an embodiment, a thickness of the plate 451 may be smaller than a diameter of the plate 451 (or a width or length of the plate 451). In an embodiment, a thickness of the plate 451 may be approximately 10 mm or less, or approximately 5 mm or less.

In an embodiment, the resonator bodies 452 may be a first dielectric material and the plate 451 may be a second dielectric material that is different than the first dielectric material. In a particular embodiment, the first dielectric material may comprise alumina (e.g., aluminum oxide Al₂O₃). Though, other dielectric materials may also be used for the first dielectric material of the resonator bodies 452. In an embodiment, the second dielectric material may comprise quartz, alumina, sapphire, MgF₂, yttrium aluminum garnet, YF₃, Y₂O₃, Y₄Al₂O₉, Y₃Al₅O₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.

Referring now to FIG. 4B, a perspective view illustration of a microwave applicator 450 is shown, in accordance with an additional embodiment. The microwave applicator 450 in FIG. 4B may be similar to the microwave applicator 450 in FIG. 4A, with the exception of the structure of the plate 451. For example, the plate 451 may comprise a coating 458. In the illustrated embodiment, the coating 458 is provided only over a bottom surface of the plate 451. That is, the surface of the plate 451 opposite from the resonator bodies 452 may be covered by the coating 458. While shown as being over only the bottom surface of the plate 451, it is to be appreciated that the coating 458 may be provided over all of the surfaces of the plate 451.

In an embodiment, the presence of the coating 458 allows for greater design flexibility of the microwave applicator 450. For example, the plate 451 may be a material selected for mechanical reliability, since the coating 458 provides protection against the plasma environment. In some instances, the plate 451 may be the same material as the resonator bodies 452. In an embodiment, the coating 458 may comprise, but is not limited to, MgF₂, YF₃, CaF₂, BaF₂, LiF, or NiF₂.

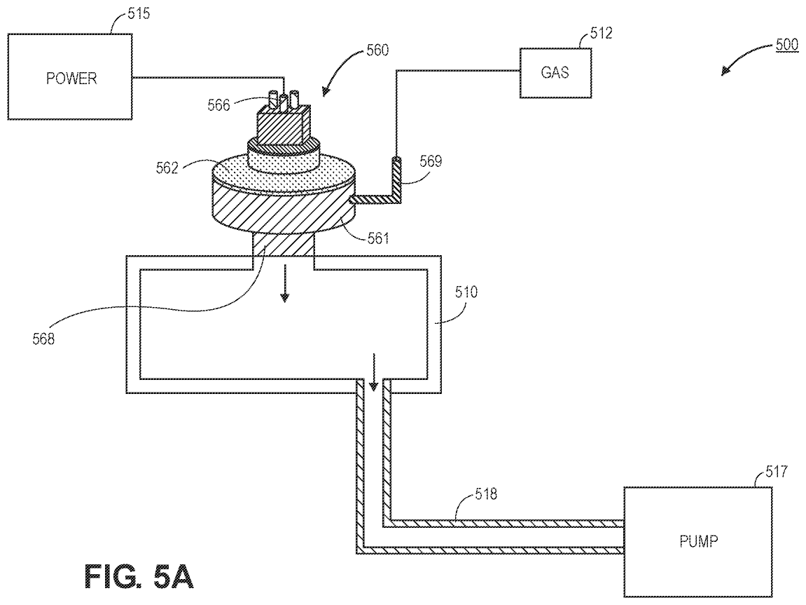

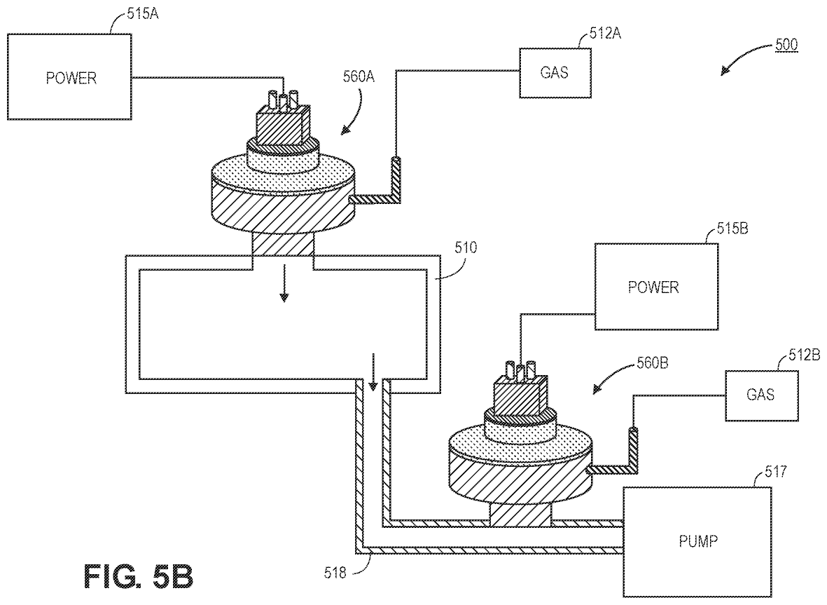

Referring now to FIG. 5A, a schematic illustration of a semiconductor processing tool 500 is shown, in accordance with an embodiment. In an embodiment, the semiconductor processing tool 500 may comprise a main processing chamber 510. In an embodiment, a substrate, such as a wafer or the like, may be provided in the main processing chamber 510 during processing. In an embodiment, the main processing chamber 510 may be a chamber suitable for maintaining sub-atmospheric pressures. For example, the main processing chamber 510 may be considered a vacuum chamber 510. The semiconductor processing tool 500 may be a tool for material deposition, material removal (e.g., etching), treatment of various layers (e.g., plasma treatment), or any other semiconductor processing operation.

In an embodiment, a remote plasma source 560 may be fluidically coupled to the main processing chamber 510. For example, exhaust 568 may couple the remote plasma source 560 to the man processing chamber 510. In an embodiment, the remote plasma source 560 may comprise a housing with a lower portion 561 and an upper portion 562. Gas input 569 may fluidically couple a gas source 512 to a chamber within the remote plasma source 560. In an embodiment, a power source 515, such as a solid state microwave power source 515, is coupled to a power input 566 of the remote plasma source 560.

In an embodiment, the remote plasma source 560 may be similar to any of the remote plasma sources described in greater detail herein. For example, the remote plasma source 560 may comprise a microwave applicator with a plate and a resonator body over the plate. In an embodiment, the plate is a different material than the resonator body. In other embodiments, the plate is lined with a coating. The plate separates the resonator body from a chamber where the plasma is formed. In some embodiments, the chamber of the remote plasma source 560 may be referred to as an antechamber.

In an embodiment, the main processing chamber 510 may be coupled to a pump 517 in order to provide sub-atmospheric pressures in the main processing chamber 510. The pump 517 may be coupled to the main processing chamber through a foreline 518.

Referring now to FIG. 5B, a schematic illustration of a semiconductor processing tool 500 is shown, in accordance with an additional embodiment. The semiconductor processing tool 500 in FIG. 5B may be similar to the semiconductor processing tool 500 in FIG. 5A, with the addition of a second remote plasma source 560B. As shown, a first remote plasma source 560A may be provided upstream of the main processing chamber 510, and a second remote plasma source 560B may be provided between the pump 515 and the main processing chamber 510 along the foreline 518. The first remote plasma source 560A may be coupled to microwave power source 515A and gas source 512A. The second remote plasma source 560B may be coupled to microwave power source 515B and gas source 512B.

In an embodiment, the second remote plasma source 560B may be similar to any of the remote plasma sources described in greater detail herein. For example, the second remote plasma source 560B may include a plate with a resonator body over the plate. The plate may be a different dielectric material than the resonator body and/or the plate may have a coating to protect the plate from the plasma environment. In an embodiment, the second remote plasma source 560B may be used in order to clean the foreline 518.

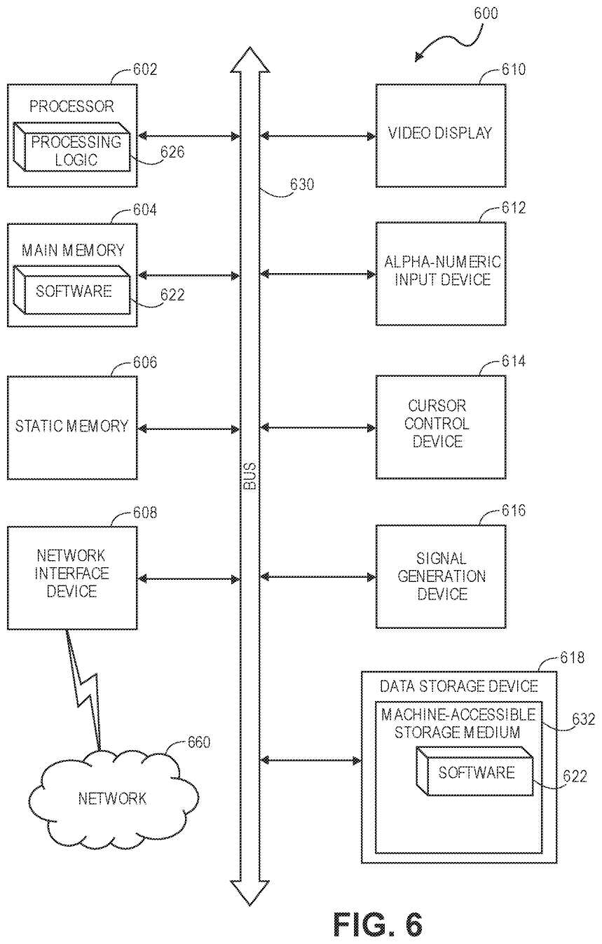

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 660 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An applicator, comprising:
a resonator body with a hole into an axial center of the resonator body, wherein the resonator body comprises a first dielectric material;
a pin inserted into the hole, wherein the pin is an electrically conductive material; and
a plate under the resonator body, wherein the plate comprises a second dielectric material that is different than the first dielectric material.

2. The applicator of claim 1, wherein a coating is on the plate.

3. The applicator of claim 2, wherein the coating covers all surfaces of the plate.

4. The applicator of claim 2, wherein the coating is over a surface of the plate opposite from the resonator body.

5. The applicator of claim 2, wherein the coating has a thickness of approximately 1,000 μm or less.

6. The applicator of claim 2, wherein the coating comprises MgF₂, YF₃, CaF₂, BaF₂, LiF, or NiF₂.

7. The applicator of claim 1, wherein the plate has a thickness that is approximately 10 mm or less.

8. The applicator of claim 1, wherein the first dielectric material comprises Al₂O₃.

9. The applicator of claim 1, wherein the second dielectric material comprises quartz, alumina, sapphire, MgF₂, yttrium aluminum garnet, YF₃, Y₂O₃, Y₄Al₂O₉, Y₃Al₅O₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.

10. The applicator of claim 1, further comprising a plurality of resonator bodies on the plate.

11. A remote plasma source, comprising:
a resonator body, wherein the resonator body comprises a first dielectric material;
a housing around the resonator body, wherein the housing comprises a volume in which a plasma can be formed; and
a plate between the resonator body and the volume, wherein the plate comprises a second dielectric material that is different than the first dielectric material.

12. The remote plasma source of claim 11, wherein a coating is on the plate.

13. The remote plasma source of claim 12, wherein the coating comprises MgF₂, YF₃, CaF₂, BaF₂, LiF, or NiF₂.

14. The remote plasma source of claim 11, wherein the first dielectric material comprises Al₂O₃.

15. The remote plasma source of claim 11, wherein the second dielectric material comprises quartz, alumina, sapphire, MgF₂, yttrium aluminum garnet, YF₃, Y₂O₃, Y₄Al₂O₉, Y₃AlO₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.

16. The remote plasma source of claim 11, further comprising:
an exhaust in the housing, wherein a radial center of the exhaust is aligned with a radial center of the resonator body.

17. The remote plasma source of claim 11, wherein a diameter of the plate is approximately 12 cm or smaller.

18. A semiconductor processing tool, comprising:
a chamber;
a remote plasma source coupled to the chamber, wherein the remote plasma source comprises:
a plate; and
a resonator body on the plate, wherein the resonator body comprises a first dielectric material, and wherein an outer surface of the plate comprises a second dielectric material that is different than the first dielectric material; and
an exhaust coupled to the chamber.

19. The semiconductor processing tool of claim 18, wherein the outer surface of the plate is a coating that surrounds the plate.

20. The semiconductor processing tool of claim 18, wherein the second dielectric material comprises quartz, alumina, sapphire, MgF₂, yttrium aluminum garnet, YF₃, Y₂O₃, Y₄Al₂O₉, Y₃Al₅O₁₂, Y₅O₄F₇, MgO, calcium fluoride, barium fluoride, lithium fluoride, fused silica, borosilicate glass, Er₂O₃, Er₃Al₅O₁₂, Er₄Al₂O₉, Gd₂O₃, Gd₄AlO₃, Gd₃Al₅O₁₂, Nd₄Al₂O, NdAlO₃, Nd₂O₃, a rare earth oxyfluoride, or a solid solution of Y₂O₃ and one or more of ZrO₂, CaF₂, SrF₂, AlF₃, ErF₃, LaF₃, NdF₃, ScF₃, CeF₄, and ZrF₄.
